(19) United States
(12) Patent Application Publication
(10) Pub. No.: US 2025/0267811 A1
(43) Pub. Date: Aug. 21, 2025

(54) RETRACTABLE USB SYSTEM AND METHOD

(71) Applicant: Thunder Cheese Limited, Sheung Wan, Hong Kong Island (HK)

(72) Inventor: William Everett Brantingham, Ma Wan, New Territories (HK)

(21) Appl. No.: 19/055,543

(22) Filed: Feb. 18, 2025

Related U.S. Application Data
(60) Provisional application No. 63/555,104, filed on Feb. 19, 2024.

(51) Int. Cl. H05K 5/02; H01R 13/453; H01R 13/629

(52) U.S. Cl. CPC H05K 5/0278; H01R 13/453; H01R 13/629

(57) ABSTRACT

Provided is a system and method for managing USB connectivity and cable organization, comprising a modular universal serial bus (USB) hub system with a main housing configured to house a retractable USB cable and a fixed USB cable. The method includes retracting the USB cable using a retraction mechanism comprising a spring and plastic disc, aligning the retractable USB cable tip horizontally upon retraction via a lofted profile within the housing, and securely attaching the housing to various surfaces using a modular mount with adhesive strips or screw holes. The system further includes interchangeable adapters stored separately and connectable to the retractable USB cable, enabling compatibility with various electronic and computer devices, and features a stackable design allowing multiple housings to be vertically assembled for simultaneous use.

### RELATED APPLICATIONS

The present application is a continuation application of U.S. Patent Application No. 63/555,104 filed Feb. 19, 2024, the disclosure of which is hereby incorporated by reference in their entireties.

### FIELD OF THE INVENTION

This disclosure relates generally to retractable cable systems and, in some non-limiting embodiments or aspects, to systems, methods, and devices for providing modular, adaptable, and space-efficient cable management solutions. Specifically, it pertains to retractable cables with interchangeable adapters and mounting mechanisms for achieving continuous external connectivity, reducing clutter, and enabling compatibility with various electronic and computer devices through efficient design, improved usability, and enhanced portability.

### BACKGROUND OF THE INVENTION

Universal serial bus (USB) technology has provided users with enhanced connectivity between computers and a wide range of peripheral devices. USB hubs, which consolidate multiple USB ports into a single housing, enable users to connect multiple devices to a computer or to each other via USB connections. While some existing USB hubs offer features like stackability, they often suffer from limitations in accessibility and cable management.

Specifically, the placement of USB ports on existing hubs can make them difficult to access, especially in constrained or cluttered environments. Additionally, existing USB hubs do not effectively address cable management, resulting in unsightly and inefficient cable arrangements that detract from workspace organization. These challenges are further compounded by the increasing demand for compact, portable, and versatile solutions that integrate seamlessly into modern workspaces and everyday life.

Furthermore, existing USB hubs lack modularity and adaptability for varied mounting configurations, such as attaching to walls, desk undersides, monitor backs, or even portable accessories like backpacks. They also fail to provide users with flexible options for securely mounting the device using removable adhesives or screws.

Accordingly, a need exists for a modular, compact USB hub system that combines versatility in mounting options, effective cable management, and user-friendly accessibility. Such a system should allow cables to exit from the hub in a direction chosen by the user and should support the integration of advanced features like retractable cables, stackable designs, and compatibility with a wide range of devices. A further need exists for a system that provides a sleek and ergonomic aesthetic while supporting robust functionality and modern USB standards, such as USB4.0, high-speed data transfer, and power delivery capabilities.

### SUMMARY OF THE INVENTION

According to non-limiting embodiments or aspects, embodiments of the present disclosure may include a modular universal serial bus (USB) hub system. The system includes a base configured to house a plurality of fixed and non-fixed electronic attachments. The base includes a main housing that encloses a retractable mechanism. In some embodiments, the system further includes a mount comprising at least one attachment mechanism. Embodiments may include at least one attachment mechanism securely attaches the main housing to an external surface. Some embodiments further include at least one USB adapter providing compatibility with various electronic and computer devices. Embodiments may include a retractable USB cable, the retractable cable being stored within the main housing.

Other embodiments of the present disclosure may also include a modular universal serial bus (USB) hub system. In some embodiments, the system may include a main housing configured to house a retractable USB cable and a fixed USB cable. The retractable USB cable being stored within the housing on a retractable mechanism comprising a spring and a plastic disc. Embodiments may include a modular mount comprising a first attachment mechanism in the form of adhesive strips and a second attachment mechanism in the form of screw holes, the modular mount is configured to securely attach the main housing to a variety of surfaces, including tabletops, walls, and monitor backs. In some embodiments, the system may include a cable management interface comprising a lofted profile configured to align the retractable USB cable tip horizontally upon retraction. Embodiments may also include a system of interchangeable adapters stored separately and connectable to the retractable USB cable for providing compatibility with various electronic and computer devices. Embodiments may also include an ergonomic, stackable design enabling multiple housings to be vertically stacked to form a tower for simultaneous use of multiple retractable USB cables.

Embodiments of the present disclosure may also include a method for managing USB connectivity and cable organization. In some embodiments, the method may provide a USB hub system with a main housing, a retractable USB cable, a fixed USB cable, and a modular mount. Other embodiments include retracting the USB cable into the main housing using a retractable mechanism comprising a spring and plastic disc. In some embodiments, the method includes aligning the retractable USB cable tip horizontally upon retraction via a lofted profile within the housing. Other embodiments include securing the USB hub system to a surface using a modular mount configured with adhesive strips or screw holes. In some embodiments, the method may also include attaching interchangeable adapters to the retractable USB cable to provide compatibility with various electronic and computer devices. Other embodiments include stacking multiple USB hub systems vertically to form a tower for simultaneous use of multiple retractable USB cables.

These and other features and characteristics of the present disclosure, as well as the methods of operation and functions of the related elements of structures and the combination of parts and economics of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

### BRIEF DESCRIPTION OF DRAWINGS

Additional advantages and details are explained in greater detail below with reference to the non-limiting, exemplary embodiments that are illustrated in the accompanying schematic figures, in which:

FIG. 1 is a perspective view of the base in isolation.

FIG. 2 is a side view of the base with a base mount attachment.

FIG. 3 is an isometric view showing a stackable base configuration.

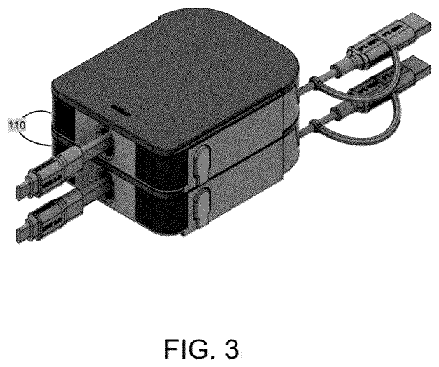

FIG. 4 is a front view of the surface mount with USB tips.

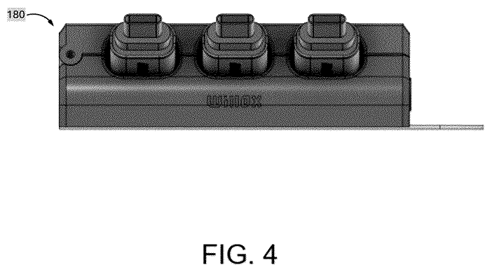

FIG. 5 is an exploded view of the pole mount showing nested grips.

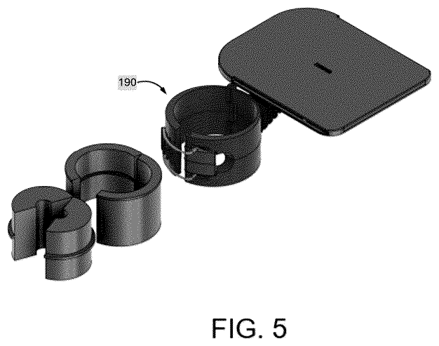

### DETAILED DESCRIPTION

For purposes of the description hereinafter, the terms “end,” “upper,” “lower,” “right,” “left,” “vertical,” “horizontal,” “top,” “bottom,” “lateral,” “longitudinal,” and derivatives thereof shall relate to the embodiments as they are oriented in the drawing figures. However, it is to be understood that the embodiments may assume various alternative variations and step sequences, except where expressly specified to the contrary. It is also to be understood that the specific devices and processes illustrated in the attached drawings, and described in the following specification, are simply exemplary embodiments or aspects of the invention. Hence, specific dimensions and other physical characteristics related to the embodiments or aspects disclosed herein are not to be considered as limiting.

No aspect, component, element, structure, act, step, function, instruction, and/or the like used herein should be construed as critical or essential unless explicitly described as such. Also, as used herein, the articles “a” and “an” are intended to include one or more items and may be used interchangeably with “one or more” and “at least one.” Furthermore, as used herein, the term “set” is intended to include one or more items (e.g., related items, unrelated items, a combination of related and unrelated items, and/or the like) and may be used interchangeably with “one or more” or “at least one.” Where only one item is intended, the term “one” or similar language is used. Also, as used herein, the terms “has,” “have,” “having,” or the like are intended to be open-ended terms. Further, the phrase “based on” is intended to mean “based at least partially on” unless explicitly stated otherwise.

As used herein, the term “communication” may refer to the reception, receipt, transmission, transfer, provision, and/or the like of data (e.g., information, signals, messages, instructions, commands, and/or the like). For one unit (e.g., a device, a system, a component of a device or system, combinations thereof, and/or the like) to be in communication with another unit means that the one unit is able to directly or indirectly receive information from and/or transmit information to the other unit. This may refer to a direct or indirect connection (e.g., a direct communication connection, an indirect communication connection, and/or the like) that is wired and/or wireless in nature. Additionally, two units may be in communication with each other even though the information transmitted may be modified, processed, relayed, and/or routed between the first and second unit. For example, a first unit may be in communication with a second unit even though the first unit passively receives information and does not actively transmit information to the second unit. As another example, a first unit may be in communication with a second unit if at least one intermediary unit processes information received from the first unit and communicates the processed information to the second unit.

As used herein, the term “computing device” may refer to one or more electronic devices configured to process data. A computing device may, in some examples, include the necessary components to receive, process, and output data, such as a processor, a display, a memory, an input device, a network interface, and/or the like. A computing device may be a mobile device. As an example, a mobile device may include a cellular phone (e.g., a smartphone or standard cellular phone), a portable computer, a wearable device (e.g., watches, glasses, lenses, clothing, and/or the like), a personal digital assistant (PDA), and/or other like devices. A computing device may also be a desktop computer or other form of non-mobile computer.

As used herein, the term “flat-profile cable” refers to a cable that has a flat cross-sectional shape, as opposed to a round or ribbon-style cable, making it good for retractable connections. Flat-profile cables are desirable for their compact form factor, tangle resistance, and controlled bending properties, which allow for smooth and consistent retraction. Their low-profile design enables efficient space utilization within mechanisms, while also reducing twisting and kinking during repeated extensions and retractions.

As used herein, the term “round-profile cable” refers to a cable that has a circular cross-sectional shape and is good for fixed USB cable connections that provide continuous connection, as opposed to a flat or ribbon-style cable. Round-profile cables are particularly suited for applications requiring smooth retraction, durability, and consistent mechanical performance. Their cylindrical design provides even stress distribution, minimizes kinking, and allows for efficient coiling within retractable mechanisms. Additionally, round-profile cables can accommodate effective shielding to reduce electromagnetic interference (EMI), ensuring reliable signal integrity for continuous data transmission.

As used herein, the term “retractable cable” refers to a cable in the retractable cable system, where “a cable is retracted back” by the process in which the cable is automatically pulled back into the housing or body of the device after being extended. This action is enabled by an internal retraction mechanism, spring-loaded, and/or the like, that winds the cable neatly onto a spool when the user releases or stops pulling it. The mechanism provides tension during extension and retraction, ensuring smooth and consistent operation. The purpose of this retraction process is to keep the cable organized, prevent tangling, and eliminate the need for manual coiling. Once retracted, the cable is securely stored within the housing, maintaining a clean and clutter-free appearance. This functionality enhances convenience for the user, allowing for quick, one-handed operation, and it also protects the cable from wear and tear caused by improper storage or excessive bending. Overall, the ability to retract the cable back into its housing makes the system efficient, user-friendly, and ideal for maintaining a tidy workspace or environment. Retracting a cable back into its housing offers several practical benefits beyond organization and tangle prevention. It protects the cable and prevents physical damage, blocks dust and moisture build-up, while also reducing strain on connectors. This retractable cable extends the cable's lifespan. Retracted cables also improve space efficiency by eliminating clutter and dangling cables, making them ideal for compact workspaces, travel, or portable use. Additionally, this mechanism enhances user convenience by enabling one-handed operation and adjustable cable lengths, ensuring the cable extends only as needed. Retracted cables provide safety by reducing trip hazards and preventing accidental pulls that can damage devices. They also provide a cleaner, more professional appearance, which is particularly valuable in organized work environments. Furthermore, retractable systems improve portability, as the compact housing makes them easy to carry without tangling.

As used herein, the term “server” may refer to or include one or more computing devices that are operated by or facilitate communication and processing for multiple parties in a network environment, such as the Internet, although it will be appreciated that communication may be facilitated over one or more public or private network environments and that various other arrangements are possible. Further, multiple computing devices (e.g., servers, point-of-sale (POS) devices, mobile devices, etc.) directly or indirectly communicating in the network environment may constitute a “system.” Reference to “a server” or “a processor,” as used herein, may refer to a previously-recited server and/or processor that is recited as performing a previous step or function, a different server and/or processor, and/or a combination of servers and/or processors. For example, as used in the specification and the claims, a first server and/or a first processor that is recited as performing a first step or function may refer to the same or different server and/or a processor recited as performing a second step or function.

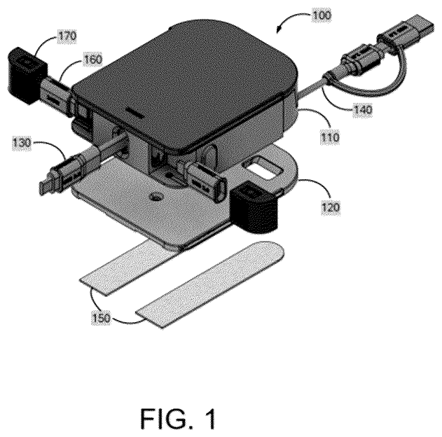

FIG. 1 is a perspective view of a modular USB system 100 according to an embodiment of the invention. The system 100 includes a retractable USB cable housing unit, or base housing, referred to herein as the base 110 and a mount 120. The base 110 serves as the core functional element of the system and is constructed from durable materials such as polycarbonate, ABS plastic, or reinforced composites. These materials ensure long-term durability, impact resistance, and heat tolerance, making the base suitable for diverse usage environments, including high-stress industrial settings.

The base 110 serves as a central hub for the system's modular and adaptable components, providing a foundation for both fixed and non-fixed electronic attachments. This modularity ensures that the system can be customized for various applications, ranging from high-performance workstations to compact, portable setups.

The base 110 may include a variety of fixed electronic attachments, which are permanently integrated into the system for consistent functionality. In one embodiment, the base may include built-in USB hubs with additional ports, such as USB-A or USB-C, to allow simultaneous connection of multiple devices. For example, a version of the base could feature three fixed USB-A ports and two USB-C ports, providing connectivity for keyboards, mice, and external storage drives.

Another fixed attachment option is the inclusion of Power Delivery (PD) ports, which can deliver up to 240 W to charge laptops, tablets, and other high-power devices. These fixed attachments could be strategically placed on the base 110 to ensure optimal accessibility, such as along the sides or rear. In advanced embodiments, the base 110 might also incorporate Ethernet ports for wired network connectivity, HDMI ports for video output, or even an SD card reader for photographers and videographers.

The base 110 may also feature embedded wireless charging pads as a fixed attachment. These pads would allow users to charge compatible smartphones, earbuds, or other Qi-enabled devices simply by placing them on the base. This would be particularly useful for desk setups where users frequently need to charge multiple devices without additional clutter.

To enhance its adaptability, the base 110 supports a variety of non-fixed electronic attachments that can be swapped or removed as needed. One example is the use of modular power bricks that attach to the base via magnetic connectors or sliding locks. These power bricks could provide additional functionality, such as a backup battery for portable use or extra USB-C outputs for charging multiple devices simultaneously.

Another non-fixed attachment option is a detachable cable organizer. This organizer could clip onto the base to hold additional cables securely in place and keep them within easy reach. Users could select different versions of the organizer based on their specific needs, such as one designed for thinner cables or another with larger loops for bulkier wires.

For enhanced connectivity, the base 110 could support non-fixed modules that plug into dedicated slots or ports. For instance, a user could attach a module with a built-in HDMI port for video output or a DisplayPort adapter for high-resolution monitors. In another embodiment, a detachable audio module could include a headphone jack and volume controls, making the system ideal for multimedia applications.

One unique embodiment is the inclusion of detachable LED light strips as a non-fixed attachment. These light strips could be attached around the edges of the base to provide customizable ambient lighting. Users could control the brightness and color of the LEDs through a companion app or physical controls on the base, enhancing both functionality and aesthetics.

In additional embodiments, the base 110 may integrate both fixed and non-fixed attachments to provide maximum flexibility and utility. For example, a fixed USB hub could be combined with a detachable SSD enclosure, allowing users to add high-speed external storage as needed. Similarly, the base 110 might include a fixed wireless charging pad alongside a removable docking station for proprietary devices, such as cameras or other specialized hardware.

For professional uses, the base 110 could also feature a modular dock for device-specific attachments. For example, a detachable module designed for gaming could include extra USB ports, RGB lighting controls, and headphone amplifiers, while a detachable productivity module might offer SD card readers, additional USB-C outputs, and network ports.

To further enhance the system's usability, both fixed and non-fixed attachments can be customized to match user preferences. For instance, users could select attachments in different colors or materials, such as matte black, brushed aluminum, or translucent plastic, to match their workspace aesthetics. Non-fixed attachments might also include interchangeable covers or skins for personalization.

Additionally, some attachments may include advanced features, such as smart charging capabilities that automatically adjust power output based on the connected device, or dynamic LED indicators that display connection status, charging progress, or data transfer activity. These features ensure that the base 110 remains a cutting-edge solution for a wide range of users, from casual consumers to professionals in specialized fields.

The retractable USB system 100 further comprises a retractable USB cable 130 having a head and body. The retractable USB cable 130 is attached to the base 110, which may vary in type and configuration depending on the target use. The retractable USB cable 130 is designed to provide reliable connectivity while minimizing cable clutter. In some embodiments, the cable may include a reinforced jacket for added durability or a braided exterior for enhanced aesthetics. In some embodiments, the retractable cable 130 may have a length from about 0.5 meters to about 1.5 meters. Ins other embodiments, retractable cable 130 length may be about 0.8 meters, or about.85 meters, or about 0.9 meters, or about 0.95 meters, or about 1 meter, or about 1.05 meters, or about 1.1 meters, or about 1.15 meters, or about 1.2 meters, or about 1.25 meters, or about 1.3 meters, or about 1.35 meters, or about 1.4 meters, or about 1.45 meters, or about 1.5 meters. The standard length of about 0.85 meters is optimized for most workspace setups, but alternative lengths (e.g., 1.5 meters or 0.5 meters) may be offered to accommodate specific user requirements.

In some non-limiting embodiments or aspects, the base 110 includes a main housing 112 that encloses a retractable mechanism, including the retractable USB cable 130 coiled around an internal spring mechanism. The spring mechanism is designed to provide consistent tension throughout the cable's lifecycle, ensuring smooth and reliable operation. In alternative embodiments, the retractable mechanism may incorporate a locking system that allows users to extend the cable 130 to a desired length and lock it in place, providing additional control over cable management.

The retractable USB cable 130, in its flat-profile configuration, offers several advantages, including resistance to tangling and enhanced flexibility. In alternate embodiments, the cable 130 may be available in a spiral-coil format, which automatically retracts to a compact shape when not in use, further improving portability. Additional variants, such as high-speed USB-C cables with enhanced shielding for data transfer rates up to 10 Gbps, may also be included in premium versions of the system.

To enhance storage and portability, the base 110 may also feature an integrated compartment for holding spare adapters or other small accessories. This compartment may include a hinged or sliding cover for easy access. In alternative designs, the storage area may be detachable, allowing users to customize the base based on their specific needs.

In some non-limiting embodiments or aspects, the retractable USB cable 130 is configured to extend partially from the front of base 110, while the fixed USB cable 140 extends from another port on the rear of base 110 for continuous external connectivity. This dual-cable configuration ensures that the system can simultaneously support temporary connections (via the retractable cable) and permanent connections (via the fixed cable). In alternative embodiments, the fixed USB cable 140 may include a modular connector, allowing users to swap the default cable with one of a different length or type.

The fixed USB cable 140, typically a round-profile cable, provides stable and reliable connectivity to a host device. In certain configurations, this cable may include additional features such as an LED indicator to display connection status or a braided exterior for enhanced durability. The length of 2 meters is standard for most setups, but variations (e.g., 3 meters or shorter lengths for compact setups) may be offered as alternatives.

In advanced embodiments, the base 110 may support multi-port configurations, with additional fixed USB ports on its rear or sides. These ports could be designed to accommodate simultaneous device charging or data transfer, further increasing the system's functionality. For example, the rear ports could include Power Delivery (PD) functionality for fast charging of smartphones or tablets, while side-mounted ports could serve as standard USB-A or USB-C connections for peripherals like keyboards and mice.

To enhance usability in specialized applications, such as video production or gaming, the base 110 may also include a built-in USB hub supporting multiple simultaneous connections. This configuration would enable professionals to connect multiple external hard drives, cameras, or other peripherals without the need for additional equipment. In some embodiments, the base 110 may integrate with the base mount 120 comprising a modular mounting platform. The modular mount 120 may also be constructed from lightweight metals, such as anodized aluminum, for applications requiring added stability or premium aesthetics. This modular platform is configured to allow multiple attachment options, such as magnetic mounts, suction cups, or clip-on mechanisms, providing greater flexibility in securing the base to different surfaces.

In some non-limiting embodiments or aspects, the base 110 is configured for modular use and can be securely attached to the base mount 120. This modularity is achieved through the inclusion of dual attachment mechanisms, such as adhesive strips and screw holes, which offer options for temporary or permanent installation. In alternate embodiments, the modular mount 120 may incorporate a quick-release mechanism, allowing the base 110 to be detached with minimal effort. Such a design is particularly useful in dynamic environments, such as coworking spaces, where users frequently reposition or reconfigure their workstations.

For additional applications, the modular mount 120 may include additional features, such as integrated cable management channels or a pivoting mechanism that allows the base 110 to rotate for better alignment. This flexibility enhances the user experience by ensuring that the retractable cable remains accessible regardless of the base's mounting position.

The base mount 120 is a flat, rectangular platform designed to stabilize the base 110 and provide a secure foundation for the retractable USB system 100. Constructed from materials such as anodized aluminum, reinforced polycarbonate, or high-strength ABS plastic, the mount is durable yet lightweight, making it suitable for a variety of work environments. The dimensions of base mount 120 may vary depending on the intended application, with smaller mounts available for compact setups and larger mounts designed for robust, high-traffic use cases.

The base mount 120 includes at least one attachment feature such as double-sided adhesive tape 150, which provides secure yet removable mounting to surfaces such as desks, walls, or other workspaces. The adhesive tape 150 is formulated to ensure strong adhesion while allowing for residue-free removal, making it ideal for temporary installations or users who frequently reposition their workstations. For permanent installations, the base mount 120 may also include screw holes (not shown) to provide a more robust and durable mounting solution. In alternative embodiments, the mount may integrate magnetic attachment points, allowing users to secure the base to metallic surfaces such as filing cabinets or monitor stands.

In some non-limiting embodiments or aspects, the retractable USB system 100 further comprises at least one USB adapter 160, which expand the system's compatibility with various electronic and computer devices. USB adapters 160 may include, but are not limited to, a USB-C to Micro USB adapter, a USB-C to Lightning adapter, a USB-C to USB-A adapter, and similar configurations. These adapters ensure seamless connectivity between the retractable USB cable 130 or fixed USB cable 140 and devices with varying port types, enabling universal usability across platforms.

The USB adapters 160 are designed with compact and lightweight profiles to maximize portability. In an example, the adapters 160 are stored in an integrated compartment 170 within the base 110 or in a separate storage case. This compartment may feature individual slots for each adapter, ensuring they remain organized and easily accessible. In alternative embodiments, the adapters may include color-coded labels or markings to help users quickly identify the appropriate adapter for their needs.

The adapters 160 serve as intermediary components, allowing users to customize their connection configurations without permanently altering the cables. For example, a user can attach a USB-C adapter to charge a smartphone, then quickly swap it for a Micro-USB adapter to connect an older device. This modular design enhances the system's versatility, enabling it to adapt to evolving user needs and technological advancements. In advanced embodiments, the adapters may include additional features, such as LED indicators to show connectivity status or reinforced housings for added durability.

For additional commercial uses, specialized adapter sets may be provided. These sets could include adapters for proprietary connectors used in specific industries, such as medical devices or industrial equipment. This ensures that the retractable USB system 100 can be used in niche applications while maintaining its core functionality and ease of use.

Users can choose and attach the appropriate adapter to the cable when needed, depending on the type of device they are connecting to. This user-friendly feature eliminates the need for multiple dedicated cables, reducing clutter and enhancing portability. The modular nature of the adapters ensures that the system remains flexible and scalable, allowing users to expand or modify their setup as new devices and standards emerge.

In alternative embodiments, the adapters 160 may include smart-chip technology to automatically detect the type of device being connected and optimize the cable's performance accordingly. For example, the adapter could detect whether the connected device supports fast charging or high-speed data transfer and adjust the power output or data rate to match. This smart functionality enhances the user experience by providing optimal performance without manual intervention.

For environments with shared or communal workstations, the modular adapter system ensures that a single retractable USB system 100 can serve a wide variety of devices. This eliminates the need for multiple hubs or adapters, streamlining operations and reducing costs. In such setups, additional security features, such as locking mechanisms for the adapters, could be included to prevent unauthorized removal or tampering.

Since devices may have varying USB ports (e.g., USB-A, USB-C, Micro-USB, Lightning), the adapters ensure the cable system can work seamlessly with a variety of devices. This universal compatibility makes the system an ideal solution for users with diverse device ecosystems, such as professionals managing multiple gadgets or households with mixed technology brands.

To accommodate future advancements in USB standards, the system may include upgradable or replaceable adapter modules. For example, as new port types or faster data transfer standards are introduced, users could purchase updated adapters compatible with the retractable USB system 100. This future-proofing ensures that the system remains relevant and useful over time.

In some embodiments, the adapters may be designed with additional ergonomic features, such as extended grips or swivel connectors, to improve usability in tight or hard-to-reach spaces. This makes the system particularly valuable for scenarios such as behind-monitor connections or densely packed workstations.

The retractable USB cable 130 and fixed USB cable 140 may be configured for high-performance applications, such as supporting USB 4.0 data transfer and charging. In alternative embodiments, the cables may be upgraded to support USB 3.0, USB 3.1, or USB-C standards, enabling higher data transfer rates and greater power delivery capabilities. For example, a USB-C cable with Power Delivery (PD) support could charge laptops or other high-power devices, expanding the system's functionality beyond traditional peripherals.

The cables 130, 140 may also include additional features, such as reinforced connectors for improved durability or braided exteriors for enhanced aesthetic appeal and resistance to wear. In some embodiments, the retractable USB cable 130 may include an integrated LED indicator to display charging or data transfer status, providing users with visual feedback during operation.

For environments requiring simultaneous connections to multiple devices, the system may include additional retractable cables or ports. For example, a premium version of the base 110 could feature two or more retractable USB cables, each with independent mechanisms and adapter compatibility. This configuration would allow users to manage multiple devices efficiently, making the system suitable for professional workstations, video production setups, or gaming environments.

In one example, retractable USB system 100 is oriented such that base 110 is mounted to the underside of a desk using the base mount 120 and adhesive tape 150. The retractable USB cable 130 extends outward for device charging and retracts back into Base 110 when not in use. Similarly, the fixed USB cable 140 provides a continuous connection to a host device.

The Base Mount 120 is a flat, rectangular platform designed to stabilize the base 110 and provide a secure foundation for the retractable USB system 100. The base mount 120 is constructed from robust materials such as anodized aluminum, high-strength ABS plastic, or a combination of polycarbonate and rubber to ensure stability and durability across various environments. The mount 120 is specifically engineered to prevent slippage, with a textured surface or rubberized base that enhances grip on smooth surfaces like glass desks or polished wood.

The base mount 120 includes attachment features such as double-sided adhesive tape 160, which offers secure yet removable mounting to surfaces such as desks, walls, or other workspaces. This adhesive tape is designed to provide strong adhesion while allowing for residue-free removal, making it suitable for users who may need to frequently reposition the system. Alternatively, the base mount 120 may include screw holes (not shown) to allow for permanent installations. These screw holes can accommodate standard or custom-sized screws, ensuring compatibility with a wide range of surfaces, including drywall, MDF boards, and monitor arms.

In alternative embodiments, the base mount 120 may incorporate additional mounting mechanisms, such as magnetic attachment points, suction cups, or clamp-based mounts. For instance, a magnetic version of the mount could be used to attach the system securely to metallic surfaces, such as filing cabinets or the steel frame of a monitor stand. Similarly, a clamp-based design could allow users to attach the mount to the edge of a desk, providing flexibility for limited workspace configurations.

In some embodiments, the mount may also include integrated cable management features, such as grooves or clips, to organize the retractable USB cable 130 and fixed USB cable 140. This additional functionality helps maintain a tidy workspace, reduces cable clutter, and ensures that the cables remain securely routed, even during active use.

In some non-limiting embodiments or aspects, the retractable USB system 100 further comprises USB adapters 150, which significantly expand the system's compatibility with a variety of electronic and computer devices. These adapters may include, but are not limited to, USB-C to Micro USB adapters, USB-C to Lightning adapters, USB-C to USB-A adapters, and similar configurations. Each adapter is designed to fit snugly onto the cables while maintaining a secure connection during use.

USB adapters 160 are compact and lightweight, ensuring that they do not add bulk to the system. In one embodiment, the adapters 160 are stored in a dedicated compartment within the base 110. This storage compartment may feature spring-loaded slots or magnetic retention to securely hold the adapters 160 in place while allowing for quick and easy access. Alternatively, the adapters may be stored in a portable carrying case included with the system, ensuring that users can keep their adapters organized and transportable.

The modularity of the adapters allows users to customize the system to their specific connectivity needs. For example, a professional working with multiple devices could seamlessly switch between a USB-C adapter for their laptop, a Micro USB adapter for an older smartphone, and a Lightning adapter for an iPad. This flexibility eliminates the need to carry multiple cables, streamlining the user's setup and reducing workspace clutter.

In advanced embodiments, the USB adapters 160 may include additional functionality, such as built-in LED indicators that signal when the adapter is properly connected or actively transferring data. Some adapters 160 may also include fast-charging capabilities or reinforced housings for added durability in high-usage environments.

Users can choose and attach the appropriate adapter to the cable when needed, depending on the type of device they are connecting to. This modular and user-friendly design ensures that the retractable USB system 100 remains compatible with a wide range of devices, including smartphones, tablets, external hard drives, and peripherals like keyboards and mice.

In alternative embodiments, the system 100 could feature smart adapters that automatically identify the connected device type and optimize the data transfer rate or power delivery accordingly. For example, the adapter 160 could adjust between USB 4.0 and USB 3.0 protocols based on the device's capabilities. This smart functionality not only enhances user convenience but also ensures optimal performance across all connected devices.

For shared or multi-user environments, such as coworking spaces or classrooms, the modular adapter system enables a single base to support multiple device types without the need for additional hubs or accessories. In such setups, the adapters may include locking mechanisms to secure them to the cables and prevent loss or unauthorized removal.

Since devices may have varying USB ports (e.g., USB-A, USB-C, Micro-USB, Lightning), the adapters ensure the cable system can work seamlessly with a variety of devices. This universal compatibility is particularly advantageous in environments where users regularly interact with devices from different manufacturers, such as tech support centers or multimedia production studios.

In alternative embodiments, the adapters 160 may include additional ergonomic features, such as extended grips for easy handling or swivel connectors that allow the cables to pivot without straining the connection. These features are particularly useful in tight or hard-to-reach spaces, such as behind desks or inside cable management channels.

To future-proof the system, modular adapters could be designed to support emerging USB standards or proprietary connectors. For example, as new port types are introduced in next-generation devices, users could simply upgrade their adapters without replacing the entire retractable USB system 100.

The retractable USB cable 130 and fixed USB cable 140 may be configured for high-performance applications, such as supporting USB 4.0 data transfer and charging. In alternative embodiments, the cables could be upgraded to support USB 3.1, USB-C with Power Delivery (PD), or Thunderbolt protocols for faster data transfer rates and higher power delivery capacities. These upgrades would make the system suitable for high-bandwidth applications, such as video editing or connecting external GPUs.

The retractable USB cable 130 may feature additional design enhancements, such as braided exteriors for added durability, tangle-free operation, or integrated LED indicators that display charging or data transfer status. Similarly, the fixed USB cable 140 may include an inline power switch or surge protection for added safety when connecting to high-power devices.

For environments requiring multiple connections, such as professional workstations or gaming setups, the base 110 could be designed to include multiple retractable USB cables. Each cable could operate independently, allowing users to connect several devices simultaneously without compromising performance or organization.

In another example, the retractable USB system 100 is configured with the adapters 160 attached to the USB cables to connect devices with differing ports. This flexibility reduces workspace clutter and maximizes compatibility, ensuring that the system remains relevant across a wide range of devices and use cases. For example, the adapters 160 could include magnetic connections for easy attachment and removal, streamlining the process of switching between devices.

The exploded perspective view showing the base 110 moved up by 50 mm to connect with the base mount illustrates the modular alignment between the base 110, mount 120, and adhesive components 150. This configuration demonstrates the precision fit and modularity of the components, ensuring seamless integration and interchangeability. The base 110, designed with alignment grooves and snap-fit connectors, enables secure attachment and effortless detachment for various mounting configurations.

The adhesive strips' 150 low-profile integration ensures a seamless look once installed, providing both aesthetic appeal and functional stability. In some embodiments, the adhesive strips may include removable tabs for repositioning or cleaning. The strips 150 are formulated with a pressure-sensitive adhesive layer that offers a secure bond on diverse surfaces such as wood, metal, glass, and plastic. For users requiring higher durability, the adhesive layer may be supplemented with additional locking mechanisms, such as magnetic panels or suction grips.

In another embodiment, the adhesive strips 150 may incorporate temperature-resistant properties, allowing the device to maintain its adhesion in environments with fluctuating temperatures, such as industrial settings or outdoor installations. Additionally, the adhesive may feature a double-sided foam core that conforms to uneven surfaces, ensuring consistent adhesion even on textured or curved substrates.

Further enhancements to the base 110 and mount 120 system may include integrated vibration-dampening pads positioned between the base and the mount. These pads not only enhance the stability of the mounted system but also reduce noise and wear from mechanical vibrations in dynamic environments, such as vehicle-mounted applications.

The modular design of the base 110 and mount 120 allows for additional accessories, such as pivoting mounts or extension arms, to be connected without altering the core assembly. For example, a pivoting mount could enable 360-degree rotation of the base, while extension arms could provide additional clearance or ergonomic positioning for specific use cases. These accessories can be retrofitted onto the existing mount design, making the system adaptable to a variety of user requirements.

For environments where discreet installations are desired, the base may also include a recessed mounting option. This embodiment involves a counter-sunk configuration in which the base sits flush with the surface, enhancing the aesthetic appeal and reducing the risk of accidental dislodgment. The recessed design can be used with or without adhesive strips, depending on the installation requirements.

To support applications requiring rapid deployment or frequent repositioning, an embodiment may include a magnetic docking system integrated into the mount and base. This system 100 allows the base to snap into place securely while enabling effortless removal. The magnets may be coated with a non-scratch material to protect delicate surfaces and maintain the device's visual integrity.

In advanced configurations, the base 110 may feature integrated LED indicators to provide visual feedback on connection status or activity. These LEDs could be designed to align with the mount's openings, ensuring visibility even when the base is fully attached. Users could customize the lighting patterns or brightness through companion software or physical controls.

Finally, in one alternative embodiment, the adhesive strips may include modular add-ons such as cable management clips or hooks. These features enable users to organize connected cables efficiently, minimizing workspace clutter while ensuring that the cables remain securely routed during active use.

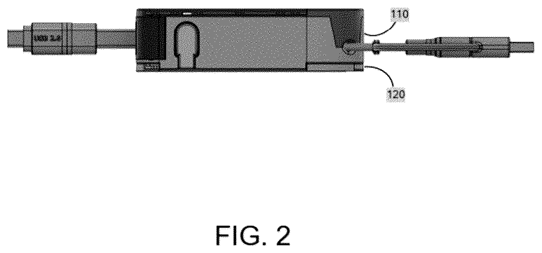

Referring again to FIG. 2, the base mount 120 provides a versatile and reliable solution for securing the base 110 to a variety of surfaces. Its design features adhesive strips for quick and tool-free installation, making it ideal for temporary setups or situations where drilling holes is not feasible. These adhesive strips are made of industrial-grade, pressure-sensitive adhesive that ensures a strong bond while allowing for residue-free removal. For additional flexibility, the mount includes screw holes to support more permanent installations, accommodating users who prefer a robust, long-term solution. In one embodiment, the screw holes are countersunk to ensure a flush, polished appearance when installed.

The base mount 120 allows for both horizontal and vertical attachment of the base 110, catering to different use cases. For instance, a horizontal attachment is suitable for desk setups where the base 110 needs to remain accessible on a flat surface, while a vertical attachment can be utilized on walls or the underside of a desk to save space. In some embodiments, the mount 120 may also include an adjustable hinge mechanism, enabling users to tilt or angle the base 110 for easier access to its USB ports. This is particularly useful for ergonomic setups or spaces with limited visibility.

In advanced embodiments, the base mount 120 could feature an integrated cable management system with built-in grooves or clips to organize and secure cables. These cable channels would reduce clutter and ensure that cables remain neatly routed, even during active use. Additionally, magnetic strips could be incorporated into the mount's design to offer an alternative attachment method, providing a secure and repositionable solution for metallic surfaces like filing cabinets or monitor stands.

The aesthetic design of the base mount complements the sleek and modern look of the base 110. Available in multiple finishes, such as matte black, brushed aluminum, and custom colors, the mount seamlessly integrates into a variety of environments, from minimalist home offices to high-traffic industrial workspaces. Its low-profile design ensures that it remains discreet while maintaining full functionality.

The system 100 may also include a surface mount 180. The surface mount 180 holds one or more retractable USB heads in a convenient location if the main retractable USB bodies are mounted somewhere out of sight and hard to reach.

The surface mount 180 is tailored for users seeking a clean and clutter-free workspace. It is specifically designed to be installed on top of, or beneath, desks or other flat surfaces. The surface mount 180 is placed in an accessible location so that a majority of the USB system 100 can be mounted out of sight. In this way, the USB system 100 is concealed while maintaining easy access to the retractable USB cable 130. The surface mount 180 includes a hinged top that provides accessible, yet secure, placement for the retractable USB cables 130, ensuring they remain properly routed and protected during use. This hinged mechanism may also include a locking feature to prevent accidental dislodgement of the cables. The hinge mechanism may also include an adjustable tension control, enabling users to customize the opening angle of the mount for ergonomic convenience. The surface mount 180 may be affixed to surfaces using double-sided adhesive tape 150.

In one embodiment, the surface mount 180 is equipped with a quick-release mechanism that allows the base 110 to be detached effortlessly for portability or reconfiguration. This feature is particularly useful for dynamic workspaces or shared environments where users need to frequently reposition or transport the system.

The surface mount 180 may also include integrated vibration-dampening pads to reduce noise and prevent wear from mechanical vibrations. This is especially advantageous in environments with frequent movement, such as coworking spaces or industrial settings. Additionally, in some embodiments, the mount could incorporate modular accessories, such as clip-on cable organizers or hooks for additional utility.

To enhance usability, the surface mount 180 could feature an optional LED indicator strip that lights up to guide users to the base's 110 location in low-light environments. The surface mount 180 could also be constructed from lightweight but durable materials, such as anodized aluminum or reinforced polycarbonate, ensuring long-term reliability while maintaining a sleek appearance. Its design ensures a seamless blend into any workspace aesthetic, with the option for custom branding or finishes to suit individual preferences.

In other embodiments, the system 100 can also be attached to a pole mount 190 adapts to car headrests, monitor arms, or thin table legs using nested rubber grips and a cam latch. The pole mount 190 offers a highly adaptable solution for securing the base 110 to cylindrical or narrow surfaces, such as car headrests, monitor arms, or thin table legs. Its design includes nested rubber grips that conform to a wide range of diameters, ensuring a secure and slip-resistant attachment. The cam latch mechanism allows for quick and easy installation or removal, providing a tool-free experience that is particularly useful for portable or temporary setups.

In one embodiment, the pole mount 190 includes a 90° tilt, and 360° swivel feature, enabling users to position the base 110 at the optimal angle for their specific needs. This adjustability is ideal for scenarios like backseat charging in vehicles or customized positioning on a monitor arm in a multimedia workstation. Advanced versions of the mount may include a locking mechanism to hold the base 110 securely in place, even during movement or vibration.

To ensure durability, the pole mount 190 is constructed from high-strength materials, such as reinforced ABS plastic or anodized aluminum. For outdoor or rugged use cases, such as attaching the base 110 to a bike handlebar, the mount could incorporate weather-resistant coatings to protect against moisture and UV exposure. In some embodiments, the rubber grips may include anti-vibration properties to further enhance stability in dynamic environments.

The pole mount 190 also supports modular attachments, such as a clip-on storage compartment for USB adapters or small accessories. This added functionality makes it a versatile solution for users who require on-the-go cable management. Additionally, the mount's compact design ensures that it does not obstruct the user's workspace or environment, maintaining a clean and professional appearance.

The retractable USB cable system is engineered to deliver high performance while maintaining flexibility and portability by including a cable that is configured to support USB 4.0 standards. The cable ensures ultra-fast data transfer rates of up to 40 Gbps, making it ideal for high-bandwidth applications such as video editing, external GPU setups, and large file transfers. The cable's power delivery capabilities of up to 240 W (5 A) allow it to charge demanding devices like laptops or high-capacity battery packs efficiently.

The cable's design features a 1.5-meter braided exterior, providing enhanced durability and resistance to tangling. The braided finish also offers a premium aesthetic and protects against wear and tear during repeated use. The compact, cone-shaped USB connector is designed to enable smooth retraction into the base 110, ensuring that the cable remains neatly stored when not in use. This compact design also facilitates easy connection in tight or crowded spaces.

To assist users in low-light environments, the cable includes a dim LED indicator at the connector tip. This LED provides visual feedback on the cable's connection status, helping users identify whether the cable is active or in use. In advanced embodiments, the LED may feature customizable colors or brightness levels, allowing users to personalize their setup.

In premium versions, the cable may include additional features such as integrated strain relief at both ends to extend its lifespan, or smart-charging technology that automatically adjusts power output based on the connected device. These features make the retractable USB cable a robust and user-friendly solution for a wide range of applications.

The method of using the retractable USB system begins with securing the modular housing to the desired surface using the provided modular mount. Users can select between adhesive strips for temporary setups or screw holes for permanent installations. Once installed, the retractable USB cable can be extended to the desired length using the spring-based retractable mechanism. The lofted profile within the housing ensures that the cable aligns horizontally during retraction, preventing tangles and facilitating smooth operation. Users may connect peripherals, such as keyboards, mice, or external storage devices, via the system's integrated USB ports, ensuring a streamlined and clutter-free workspace.

To enhance device compatibility, the system allows for interchangeable adapters to be attached to the retractable cable. Depending on the user's requirements, adapters such as USB-C, Micro-USB, or Lightning can be quickly swapped to connect to diverse devices. This modularity ensures that the product remains functional across various technology ecosystems, including smartphones, tablets, and laptops. For professional environments, specialized adapters, such as HDMI or Ethernet modules, can be attached to meet niche application requirements.

The system is designed for flexibility and portability. For dynamic environments, such as coworking spaces or vehicles, users can reposition the modular mount or use alternative mounting options, such as pole mounts or surface mounts. For travel, the compact base housing easily fits into bags, while retractable and detachable features keep cables organized and tangle-free. In vehicles, the pole mount enables secure attachment to headrests, allowing passengers to charge or connect devices during transit.

In advanced configurations, the retractable USB system supports future-ready applications. For instance, users can leverage USB4.0 compatibility for high-speed data transfer and power delivery up to 240 W, ideal for external GPUs, 8K displays, and fast-charging high-capacity batteries. Additionally, the system's modularity can extend into IoT setups, allowing devices to interface seamlessly with smart home ecosystems via attached sensors or hubs.

For shared environments, such as classrooms or coworking spaces, the system supports simultaneous connections through its modular and stackable design. Users can connect multiple retractable USB systems vertically, forming a tower configuration for multi-user access. This setup enables efficient cable management and device connectivity for collaborative projects, multimedia production, or gaming setups. LED indicators embedded in the housing guide users in identifying active connections in dimly lit environments.

To maintain the system's longevity, users can periodically clean the retractable mechanism and replace adapters or cables as needed. Future upgrades, such as next-generation adapters or enhanced retractable mechanisms, can be integrated seamlessly, ensuring the system remains relevant in evolving technology landscapes. For example, as new USB standards or connectors are introduced, users can replace modular components without altering the core system.

Manufacturing the retractable USB system begins with the selection of durable and lightweight materials. The base is typically constructed from injection-molded ABS plastic or polycarbonate for impact resistance, while components such as the modular mount may utilize anodized aluminum for enhanced stability. The retractable mechanism, including the spring and spool, is precision-manufactured to ensure consistent tension and smooth retraction.

The retractable USB cable is designed with a flat-profile or round-profile configuration, depending on the intended use. The cable is reinforced with braided or jacketed exteriors to enhance durability and aesthetics. Adapter compatibility is ensured by machining modular connectors to exacting tolerances, allowing for secure attachment and seamless data transmission. Each adapter is designed with lightweight materials and compact profiles to maximize portability.

The retractable mechanism is assembled by coiling the USB cable around a spring-loaded spool inside the housing. This spool is calibrated to maintain optimal retraction tension throughout the cable's lifecycle. A locking mechanism may be added to enable users to extend the cable to a specific length and lock it in place. The assembled mechanism may be tested for durability and retraction smoothness to ensure reliability in high-use scenarios.

The mount is engineered to support multiple attachment methods, including adhesive strips, screw holes, and magnetic connectors. During production, adhesive strips may be pre-applied to mounts using automated machinery, ensuring consistency and strong adhesion. Screw holes are precision-drilled to accommodate a range of installation surfaces. Magnetic panels are integrated into select mounts to allow repositionable configurations.

The base is further equipped with advanced features, such as embedded LED indicators and wireless charging pads. LED circuits are installed onto the housing's internal PCB to provide status updates for charging and data transfer. Wireless charging coils are embedded into the base, enabling users to charge compatible devices by simply placing them on the system. Each advanced feature is tested for functionality before final assembly.

The final product undergoes may undergo quality assurance testing to ensure compliance with USB standards and performance specifications. Tests include data transfer rate verification, retraction mechanism durability, and adapter connectivity validation.

1. A modular universal serial bus (USB) hub system, the system comprising:
a base configured to house a plurality of fixed and non-fixed electronic attachments, wherein the base include a main housing that encloses a retractable mechanism;
a mount comprising at least one attachment mechanism, wherein the at least one attachment mechanism securely attaches the main housing to an external surface;
at least one USB adapter providing compatibility with various electronic and computer devices; and
a retractable USB cable, the retractable cable being stored within the main housing.

2. The modular USB system of claim 1, further comprising a fixed USB cable extending from a port in the base.

3. The modular USB system of claim 1, further comprising a pole mount that is configured to attach the system to cylindrical or narrow surfaces.

4. The modular USB system of claim 1, wherein the at least one USB adapters is selected from the group consisting of USB-C to Micro USB adapters, USB-C to Lightning adapters, and USB-C to USB-A adapters.

5. The modular USB system of claim 1, wherein the USB adapters are stored in a dedicated compartment with the base.

6. The modular USB system of claim 1, wherein the at least one attachment mechanism is adhesive strips.

7. The modular USB system of claim 1, wherein the mount is a pivoting mount configured to enable the base to rotate up to 360 degrees.

8. The modular USB system of claim 1, wherein the retractable USB cable has a length that is dynamically adjusted between about 0.85 to about 1.5 meters.

9. A modular universal serial bus (USB) hub system, comprising:
a main housing configured to house a retractable USB cable and a fixed USB cable, the retractable USB cable being stored within the housing on a retractable mechanism comprising a spring and a plastic disc;
a modular mount comprising a first attachment mechanism in the form of adhesive strips and a second attachment mechanism in the form of screw holes, the modular mount is configured to securely attach the main housing to a variety of surfaces, including tabletops, walls, and monitor backs;
a cable management interface comprising a lofted profile configured to align the retractable USB cable tip horizontally upon retraction;
a system of interchangeable adapters stored separately and connectable to the retractable USB cable for providing compatibility with various electronic and computer devices; and
an ergonomic, stackable design enabling multiple housings to be vertically stacked to form a tower for simultaneous use of multiple retractable USB cables.

10. The modular USB system of claim 9, wherein the retractable USB cable supports USB 4.0 specifications, providing 40 Gbps data transfer and power delivery up to 240 W.

11. The modular USB system of claim 9, wherein the modular mount is detachable and includes dimensions for integration with portable accessories, such as backpacks or mobile workstations.

12. The modular USB system of claim 9, wherein the retractable mechanism is configured to support a retractable USB cable length of up to 1.5 meters while maintaining smooth retraction.

13. The modular USB system of claim 9, further comprising an integrated LED indicator within the housing, configured to emit a dim light to aid nighttime use.

14. The modular system of claim 9, wherein the modular mount includes rails that allow the main housing to be removed or replaced with minimal effort.

15. The modular USB system of claim 9, further comprising at least one USB port positioned within the main housing and operable to receive one or more peripheral devices.

16. A method for managing USB connectivity and cable organization, comprising:
providing a USB hub system with a main housing, a retractable USB cable, a fixed USB cable, and a modular mount;
retracting the USB cable into the main housing using a retractable mechanism comprising a spring and plastic disc;
aligning the retractable USB cable tip horizontally upon retraction via a lofted profile within the housing;
securing the USB hub system to a surface using a modular mount configured with adhesive strips or screw holes;
attaching interchangeable adapters to the retractable USB cable to provide compatibility with various electronic and computer devices; and
stacking multiple USB hub systems vertically to form a tower for simultaneous use of multiple retractable USB cables.

17. The method of claim 16, further comprising the step of transmitting data at a speed of 40 Gbps using the USB 4.0 specifications supported by the retractable USB cable.

18. The method of claim 16, wherein the modular mount is attached to a portable accessory, such as a backpack, by threading straps through the screw holes.

19. The method of claim 16, further comprising the step of emitting a dim light from an integrated LED indicator within the main housing to improve visibility in low-light conditions.

20. The method of claim 16, wherein the retracted USB cable length is dynamically adjusted between about 0.85 to about 1.5 meters based on user preferences or device requirements.
